(19) United States
(12) Patent Application Publication
(10) Pub. No.: US 2024/0203934 A1
(43) Pub. Date: Jun. 20, 2024

(54) APPARATUS FOR BONDING ELECTRONIC COMPONENT, METHOD FOR BONDING ELECTRONIC COMPONENT, AND METHOD FOR MANUFACTURING LIGHT-EMITTING DIODE DISPLAY

(71) Applicant: Stroke Precision Advanced Engineering Co., Ltd., Taoyuan City (TW)

(72) Inventors: Chingju Lin, Taoyuan City (TW); Sheng-Che Huang, Taoyuan City (TW)

(73) Assignee: Stroke Precision Advanced Engineering Co., Ltd., Taoyuan City (TW)

(21) Appl. No.: 18/518,457

(22) Filed: Nov. 23, 2023

Related U.S. Application Data
(60) Provisional application No. 63/432,384, filed on Dec. 14, 2022.

(30) Foreign Application Priority Data
Feb. 24, 2023 (TW) 112106952

(51) Int. Cl. H01L 23/00; H01L 21/67; H01L 21/683

(52) U.S. Cl. CPC H01L 24/80; H01L 21/67115; H01L 21/6835; H01L 25/0753; H01L 2221/68363; H01L 2224/80006; H01L 2224/80224; H01L 2924/12041

(57) ABSTRACT

An apparatus for bonding an electronic component including a first carrier, a second carrier, a driving mechanism, and a substrate adjustment mechanism is disclosed. The first carrier is configured to carry a first substrate and has a first carrying surface. The second carrier is configured to carry a second substrate and has a second carrying surface. The driving mechanism enables the first carrier and the second carrier to act in close proximity to each other and far away from each other. The substrate adjustment mechanism enables the first substrate and the second substrate disposed to be in a non-parallel configuration.

### CROSS-REFERENCE TO RELATED APPLICATION

This application claims the priority benefits of U.S. provisional application Ser. No. 63/432,384, filed on Dec. 14, 2022, and Taiwanese application serial no. 112106952, filed on Feb. 24, 2023. The entirety of each of the above-mentioned patent applications is hereby incorporated by reference herein and made a part of this specification.

### BACKGROUND

### Technical Field

This disclosure relates to an apparatus, and method, and in particular to an apparatus for bonding an electronic component, a method for bonding an electronic component, and a method for manufacturing a light-emitting diode display.

### Description of Related Art

In the manufacturing process of electronic products, there are often steps involved in the transfer of electronic devices. For example, in the manufacturing process of a light-emitting diode display panel (LED display), a pick-and-place apparatus is often used to transfer the LED from one substrate to another substrate. However, the operation of the pick-and-place apparatus is more complicated and/or the throughput or yield of the above method may be lower.

### SUMMARY

The disclosure provides an apparatus for bonding substrates, an equipment for transferring an electronic device, a method for bonding an electronic device, and a method for manufacturing a light-emitting diode display.

An apparatus for bonding an electronic component of the disclosure includes a first carrier configured to carry a first substrate and having a first carrying surface, a second carrier configured to carry a second substrate having the electronic component to be bonded, and having a second carrying surface, a driving mechanism enabling the first carrier and the second carrier to move close to and far away from each other, a substrate adjustment mechanism enabling the carried first substrate and the second substrate to be in a non-parallel configuration, and an energy beam generator generating an energy beam towards the first carrier and the second carrier.

A method for bonding an electronic component of the disclosure includes the following steps: providing a first substrate having a bonded surface; providing a second substrate having a surface on which the electronic component to be bonded is disposed; placing the first substrate and the second substrate in a way that the bonded surface of the first substrate faces the surface of the second substrate on which the electronic component to be bonded is disposed; arranging the first substrate and the second substrate to be in a non-parallel configuration; moving the first substrate and/or the second substrate to approach each other in the non-parallel configuration till the first substrate contacts the second substrate at a contact region; continuing to move the first substrate and/or the second substrate to achieve a full contact of the first substrate and the second substrate from the mere contact of the contact region; and applying an energy beam to bond the electronic component from the second substrate onto the bonded surface of the first substrate.

A method for manufacturing a light-emitting diode display of the disclosure includes the following steps: bonding the light-emitting diode using the method for bonding an electronic component, wherein the electronic component is a light-emitting diode.

Based on the above, the apparatus of the disclosure may be configured to bond the substrates, and the equipment of the disclosure may be configured to transfer the electronic device in a relatively simple manner. Furthermore, the apparatus, equipment and/or method for bonding the electronic device may improve productivity or yield.

To make the aforementioned more comprehensive, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate example embodiments of the disclosure and, together with the description, serve to explain the principles of the disclosure.

FIG. 1A to FIG. 1G are schematic partial side views of a method for bonding an electronic component according to an embodiment of the disclosure.

FIG. 2A to FIG. 2F are schematic partial side views of a method for bonding an electronic device according to another embodiment of the disclosure.

### DESCRIPTION OF THE EMBODIMENTS

The content of the following embodiments is illustrative and not restrictive. Also, descriptions of well-known apparatuses, methods and materials may be omitted so as not to obscure the description of the various principles of the disclosure. Directional terms (e.g., up, down) used herein are intended to refer only to conventional terms used or corresponding to the figures in the drawings and are not intended to imply absolute orientation. In addition, unless the content clearly dictates otherwise, the singular forms “a”, “one”, “the” or the form not specifically referring to a quantity may include one or multiple, i.e., include “at least one”.

In some of the drawings, for the sake of clarity, some devices, components, or layers may be enlarged, reduced, or omitted at specific locations or specific orientations. For example, in all drawings, electronic components (but not limited to) may be shown enlarged.

Similar components are denoted by the same reference numerals, and have similar functions, materials, or formation methods, and descriptions thereof are omitted. It will be apparent to those having ordinary skill in the art that the disclosure can be practiced in other embodiments that depart from the specific details disclosed herein, from the teachings of the embodiments and the corresponding illustrations.

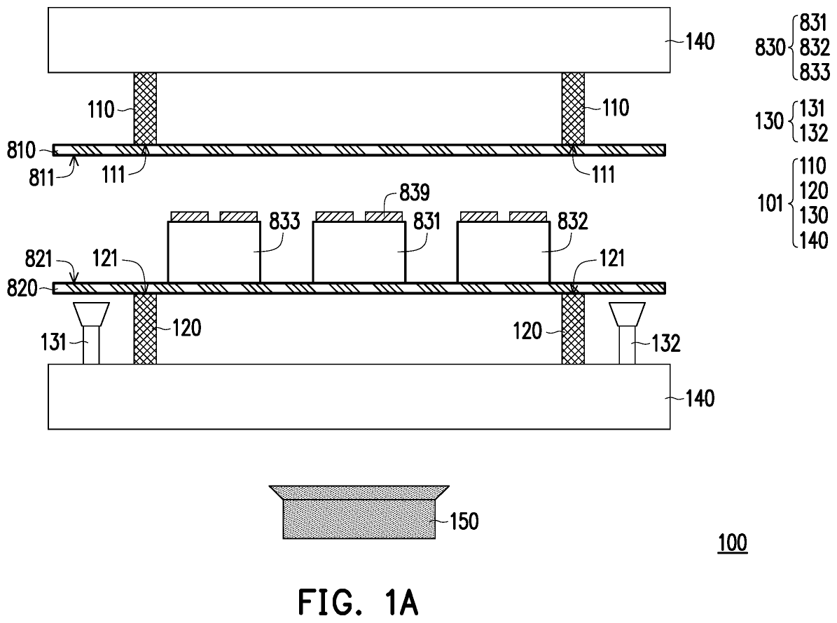

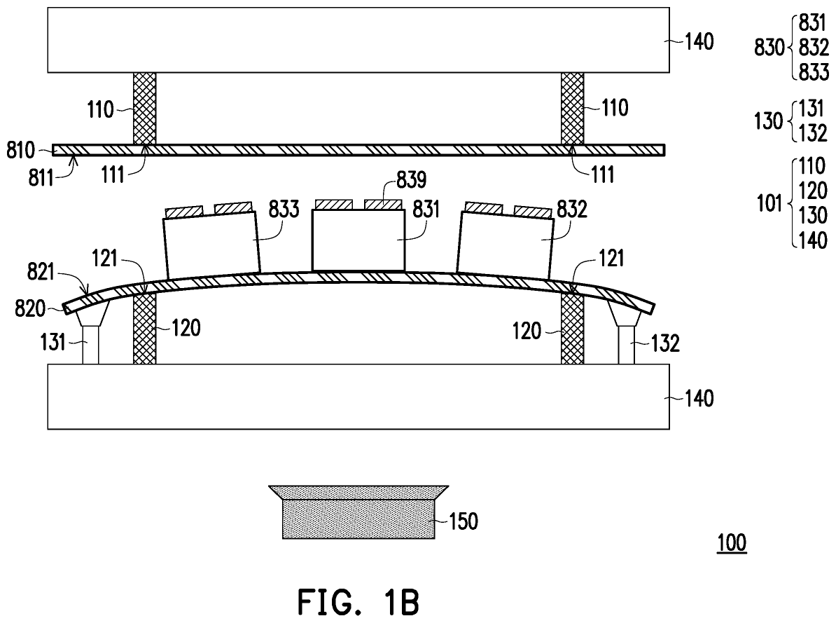

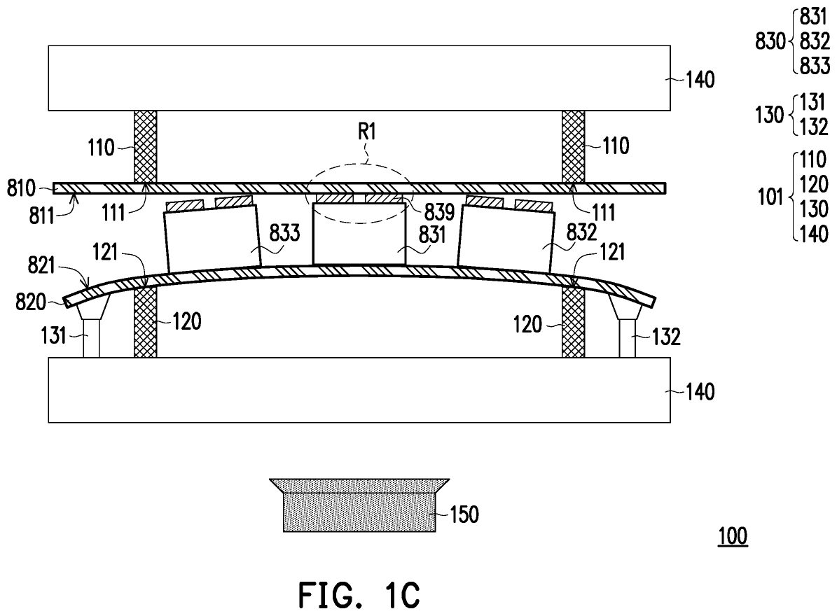

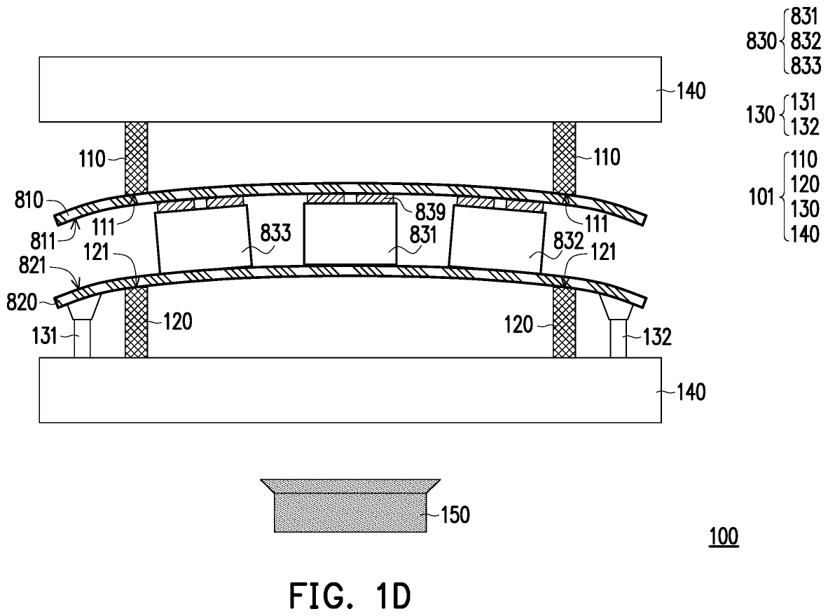

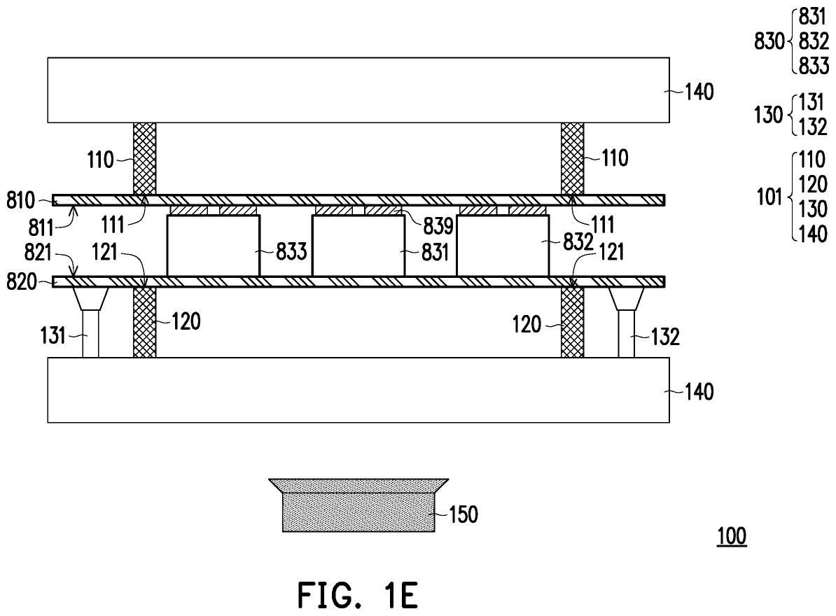

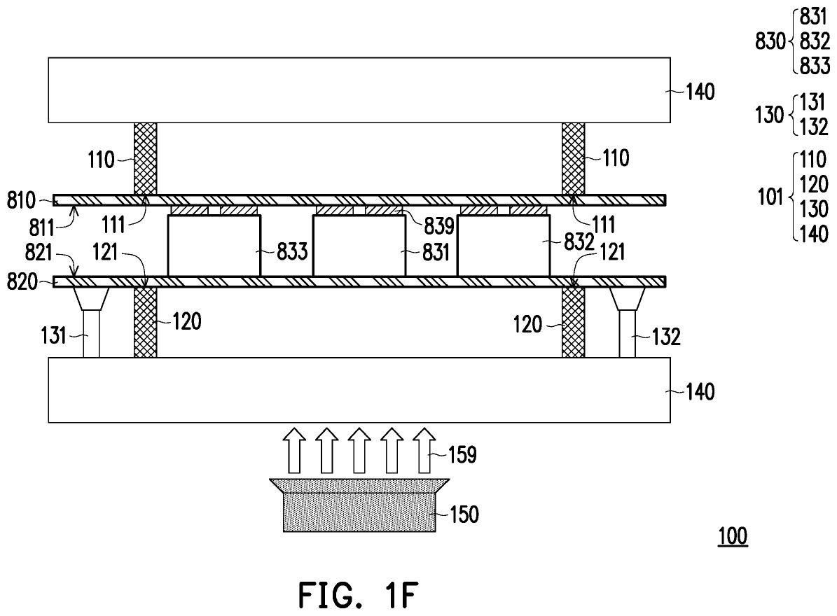

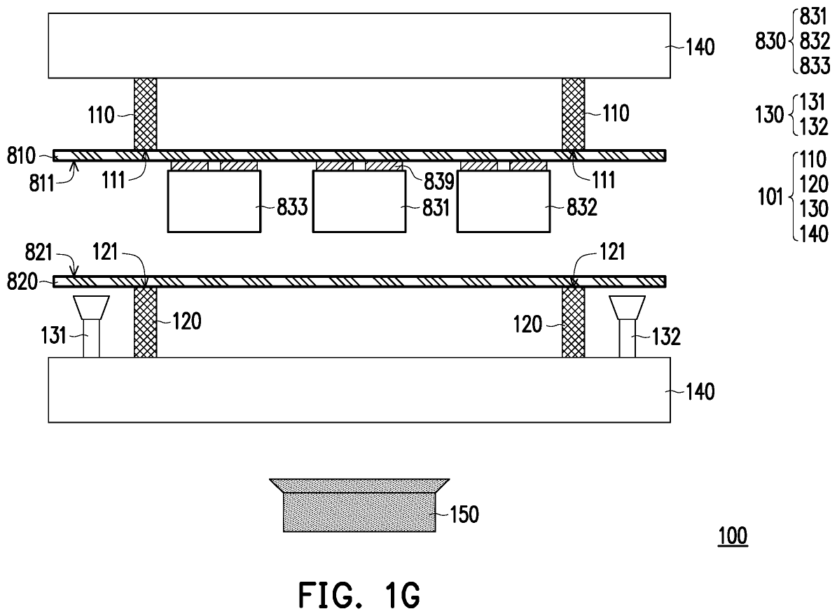

FIG. 1A to FIG. 1G are schematic partial side views of a method for bonding an electronic component according to an embodiment of the disclosure, including a corresponding equipment for attaching substrates and/or an apparatus for transferring an electronic component.

Referring to FIG. 1A or other similar diagrams, an apparatus for bonding an electronic component (may be referred to as: an apparatus) 100 may include an equipment for attaching substrates (may be referred to as: an equipment) 101 and an energy beam generator 150, and may be adapted to enable an electronic component 830 to be transferred from a second substrate 820 to a first substrate 810 (details will be described later). The equipment for attaching substrates 101 may include a first carrier 110, a second carrier 120, a driving mechanism 140, and a substrate adjustment mechanism 130.

The first carrier 110 may have a first carrying surface 111, so that the first carrier 110 may be adapted to carry the first substrate 810.

In an embodiment, the first carrier 110 may include a frame. For example, the first carrier 110 may include a metal frame, a plastic frame, a frame similar to the foregoing, or a combination of the foregoing. In an embodiment, the first carrying surface 111 of the first carrier 110 may include a hollow surface. For example, the first carrying surface 111 may include a surface of the frame and/or a hollow surface surrounded thereby.

In an embodiment, the first carrier 110 may include a platform having a body. For example, the first carrier 110 may include a physical platform of sheet metal, sheet plastic, an analog of the foregoing, or a combination of the foregoing. In an embodiment, the first carrying surface 111 of the first carrier 110 may include a physical surface.

In an embodiment, the first substrate 810 may be carried on the first carrying surface 111 of the first carrier 110 (which may be below as in FIG. 1A or other similar drawings) by clamping, snapping, sticking, adsorbing, or other appropriate methods.

In an embodiment, the first substrate 810 may be deformed correspondingly by applying force to an appropriate part of the first substrate 810.

The second carrier 120 may have a second carrying surface 121, so that the second carrier 120 may be adapted to carry the second substrate 820.

In an embodiment, all parts of the second carrying surface 121 may be located at the same or similar level.

In an embodiment, second carrier 120 may include a frame. For example, the second carrier 120 may include a metal frame, a plastic frame, a frame similar to the foregoing, or a combination of the foregoing. In an embodiment, the second carrying surface 121 of the second carrier 120 may include a hollow surface. For example, the second carrying surface 121 may include a surface of the frame and/or a hollow surface surrounded thereby.

In an embodiment, the second carrier 120 may include a platform having a body. For example, the second carrier 120 may include a physical platform of sheet metal, sheet plastic, an analog of the foregoing, or a combination of the foregoing. In an embodiment, the second carrying surface 121 of the second carrier 120 may include a physical surface.

In an embodiment, the second substrate 820 may be placed on the second carrying surface 121 of the second carrier 120 by natural gravity (which may be above as in FIG. 1A or other similar drawings). In an embodiment, the second substrate 820 may be carried on the second carrying surface 121 of the second carrier 120 by clamping, snapping, sticking, adsorbing, or other appropriate methods.

In an embodiment, the second substrate 820 may be deformed correspondingly by applying force to an appropriate part of the second substrate 820.

The driving mechanism 140 may be adapted to directly or indirectly actuate at least one of the first carrier 110 and the second carrier 120, so that the first carrier 110 or the second carrier 120 may be moved and/or rotated in a corresponding direction according to design requirements. For example, the driving mechanism 140 may enable the first carrier 110 and the second carrier 120 to move close to each other or far away from each other.

In an embodiment, for example, the driving mechanism 140 may include movable modules (e.g., horizontal moving module, vertical moving module, rotating moving module, or a combination thereof), which may include corresponding hardware or software, or may be further combined with auxiliary components. For example, the movable module may have power supply devices, motors, belts, gears, and other related components, etc., which are not limited in the disclosure. The related components include, for example, communication components, power components, etc., which are not limited in the disclosure. The software includes, for example, spatial position calculation software, error logging software, communication software, etc., which are not limited in the disclosure. The auxiliary components include, for example, moving rails, moving shafts, shock adsorbing elements, positioning devices, etc., which are not limited in the disclosure.

The substrate adjustment mechanism 130 may enable the first substrate 810 carried on the first carrying surface 111 of the first carrier 110 and the second substrate 820 carried on the second carrying surface 121 of the second carrier 120 to be in a non-parallel configuration.

In an embodiment, the substrate adjustment mechanism 130 may include at least two suction nozzles 131 and 132. Referring to the side shown in FIG. 1A, the substrate adjustment mechanism 130 may include at least two suction nozzles 131 and 132, but the disclosure is not limited thereto. In other undrawn sides or other similar undrawn embodiments, the substrate adjustment mechanism 130 may further include other suction nozzles identical or similar to the suction nozzles 131 and 132.

The two suction nozzles 131 and 132 are disposed opposite to each other and are disposed near the second carrier 120. For example, in a direction substantially parallel to the second carrying surface 121, the second carrier 120 is located between the suction nozzle 131 and the suction nozzle 132, and the suction nozzle 131 and the suction nozzle 132 are respectively near the second carrier 120.

In an embodiment, the two suction nozzles 131 and 132 are not located between the first carrying surface 111 and the second carrying surface 121.

In an embodiment, in a direction substantially perpendicular to the first carrying surface 111 or the second carrying surface 121, the two suction nozzles 131 and 132 do not overlap the first carrying surface 111 or the second carrying surface 121.

In an embodiment, a height of the two suction nozzles 131 and 132 may be adjusted by an appropriate movable module (e.g., a vertical moving module).

The two suction nozzles 131 and 132 may pump air in a direction away from the second carrying surface 121 to adsorb an object. For example, one end of a gas pipeline of the suction nozzles 131 and 132 may face the second substrate 820 on the second carrier 120, and the other end of the gas pipeline of the suction nozzles 131 and 132 may be connected to a corresponding air pumping apparatus (e.g., an air pump). In this way, at least one part of the second substrate 820 may be deformed by actuating the air pumping apparatus, so that this part gradually approaches the suction nozzles 131 and 132 and is adsorb by the suction nozzles 131 and 132.

In an embodiment, a method for bonding the electronic component 830 from the second substrate 820 to the first substrate 810 by the apparatus for bonding an electronic component (may be referred to as: the apparatus) 100 may be as follows.

Referring to FIG. 1A, the first substrate 810 is placed on the first carrying surface 111 of the first carrier 110; and/or, the second substrate 820 is placed on the second carrying surface 121 of the second carrier 120. It should be noted that the disclosure does not limit the placement order of the first substrate 810 and the second substrate 820.

In an embodiment, the second substrate 820 may include a bare substrate, but the disclosure is not limited thereto. For example, the second substrate 820 may be a bare glass plate, a bare plastic plate, a bare metal plate, an analog of the foregoing, or a combination of the foregoing.

In an embodiment, the electronic component 830 may be adapted to be placed on a surface 821 of the second substrate 820. In an embodiment, there may be an appropriate temporary adhesive layer between the second substrate 820 and the electronic component 830 disposed thereon. The temporary adhesive layer may include a pyrolytic adhesive layer, a photolytic adhesive layer, or a photo thermolytic adhesive layer, but the disclosure is not limited thereto.

In an embodiment, the electronic component 830 may be placed on the surface 821 of the second substrate 820, and then the second substrate 820 having the electronic component 830 disposed thereon is placed on the second carrying surface 121 of the second carrier 120. In an embodiment, the second substrate 820 may be placed on the second carrying surface 121 of the second carrier 120, and then the electronic component 830 is placed on the surface 821 of the second substrate 820 that has been placed on the second carrier 120.

In an embodiment, the first substrate 810 may have a bonded surface 811 onto which the electronic component 830 may be bonded. For example, the first substrate 810 may include a contact pad adapted to be bonded, and a surface on which the contact pad is located may be called the bonded surface 811. In an embodiment, the first substrate 810 may include a circuit board or a thin film transistor array substrate (TFT array substrate), but the disclosure is not limited thereto.

Three electronic components 830 are exemplarily shown in FIG. 1A, but the disclosure is not limited thereto. Each electronic component 830 may have a corresponding conductive connector 839. The conductive connector 839 may include a solder. An electronic component 831 (one of the three electronic components 830) is located between an electronic component 832 (another one of the three electronic components 830) and an electronic component 833 (the other one of the three electronic components 830), but the disclosure is not limited thereto. In an overhead view, the electronic component 831 is located at or close to a central area of the second substrate 820. In a top view, the electronic components 832 and 833 are not located at or are far away from the central area of the second substrate 820. In a top view, the electronic components 832 and 833 are located at or close to a peripheral area of the second substrate 820. That is, the electronic component 832 and/or the electronic component 833 are closer to edges of the second substrate 820 than the electronic component 831.

Referring to FIG. 1A, the bonded surface 811 of the first substrate 810 is enabled to face the surface 821 of the second substrate 820 having the electronic component 830 to be bonded. For example, the driving mechanism 140 may be configured to enable the surface 821 of the second substrate 820 having the electronic component 830 to be bonded disposed thereon and the bonded surface 811 of the first substrate 810 to face each other.

Referring to FIG. 1A to FIG. 1B, the first substrate 810 and the second substrate 820 are in a non-parallel configuration.

In an embodiment, after the bonded surface 811 of the first substrate 810 is enabled to face the surface 821 of the second substrate 820 having the electronic component 830 to be bonded, at least two suction nozzles (e.g., the suction nozzle 131 and the suction nozzle 132) may be configured to pump air in a direction away from the second carrying surface 121, so that the second substrate 820 having the electronic components 830 to be bonded disposed thereon is deformed correspondingly. In this way, the surface 821 of the second substrate 820 may be made to appear curved, and the first substrate 810 is not parallel to the second substrate 820.

In an embodiment, by adjusting the suction force of the suction nozzles 131 and 132, the material of the second substrate 820 and/or the arrangement of the second substrate 820, a protrusion (i.e., a position closest to the first substrate 810) of the surface 821 appearing curved may be adjusted. Referring to FIG. 1B, the protrusion of the surface 821 appearing curved may be basically located at or close to a center of the surface 821. That is, compared with other electronic components (e.g., electronic components 832 and 833 different from the electronic component 831), the electronic component 831 placed corresponding to the protrusion may be closer to the first substrate 810. In a non-illustrated embodiment, the protrusion may deviate from the center of the surface 821.

In an embodiment, after the suction nozzles 131 and 132 adsorb the second substrate 820, they may be moved in a direction far away from the second carrying surface 121 (e.g., by lowering a height of the suction nozzles 131 and 132), i.e., lower than the second carrying surface 121, so that the surface 821 of the second substrate 820 appears curved.

Referring to FIG. 1B to FIG. 1C, for example, the first substrate 810 and the second substrate 820 in a non-parallel configuration may be enabled to approach each other by the driving mechanism 140 and to contact each other to form a corresponding contact region R1 (marked in FIG. 1C).

In an embodiment, the contact region R1 is basically located in a central area of the first substrate 810 and the second substrate 820. In an embodiment, compared with other electronic components (e.g., the electronic components 832 and 833 different from the electronic component 831), the electronic component 831 placed corresponding to the protrusion may contact a corresponding position of the first substrate 810 earlier. For example, the conductive connector 839 on the electronic component 831 may contact a corresponding connection pad (not shown) on the bonded surface 811 of the first substrate 810.

In an embodiment, in the case where a thickness of the electronic component 830 and a thickness of the second substrate 820 are greatly different (e.g., the thickness of the second substrate 820 may be more than 10 times the thickness of the electronic component 830, or even more than 100 times the thickness of the electronic component 830), it may be considered that the electronic component 831 corresponding to the protrusion and a part of the second substrate 820 are in contact with the first substrate 810 to form a corresponding contact region. For example, the electronic component 830 may be a sub-millimeter light-emitting diode (Mini LED) or a micro-light emitting diode (Micro LED, μLED), and the second substrate 820 may be a glass plate or polymer plate with corresponding dimensions.

Referring to FIG. 1C to FIG. 1D, in an embodiment, for example, the driving mechanism 140 may enable the first substrate 810 and the second substrate 820 in the non-parallel configuration to further approach each other, so that the two substrates (i.e., the first substrate 810 and second substrate 820) gradually contact with other regions from the contact region R1 until the two substrates 810 and 820 are completely in contact.

In an embodiment, the first substrate 810 may be released so that the two substrates (i.e., the first substrate 810 and the second substrate 820) gradually contact with other regions from the contact region R1.

In an embodiment, the conductive connector 839 on other electronic components (e.g., the electronic components 832 and 833) different from the electronic component 831 may contact the corresponding connection pad on the bonded surface 811 of the first substrate 810.

In an embodiment, in the case where the thickness of the electronic component 830 and the thickness of the second substrate 820 are greatly different (e.g., the thickness of the second substrate 820 may be more than 10 times the thickness of the electronic component 830, or even more than 100 times the thickness of the electronic component 830), it may be considered that the electronic components 832 and 833 and the second substrate 820 are in contact with the first substrate 810.

Referring to FIG. 1D to FIG. 1E, in an embodiment, after the two substrates 810 and 820 are completely in contact, the heights of the two suction nozzles 131 and 132 may be adjusted so that the surface 821 of the second substrate 820 appears flat. For example, the heights of the two suction nozzles 131 and 132 and the second carrying surface 121 may be in the same plane, and the surface 821 of the second substrate 820 may appear flat. In an embodiment, by adjusting the heights of the two suction nozzles 131 and 132, the bonded surface 811 of the first substrate 810 may also appear as a corresponding flat surface.

Referring to FIG. 1E to FIG. 1F, in an embodiment, for example, the energy beam generator 150 may generate an energy beam 159. The energy beam 159 is directed towards and applied to the first substrate 810 or the second substrate 820, so that the electronic component 830 to be bonded (e.g., the electronic component 831) on the second substrate 820 is bonded onto the bonded surface 811 of the first substrate 810.

In an embodiment, the energy beam 159 may at least partially melt the conductive connector 839 of the corresponding electronic component 831, so that at least a part of the melted conductive connector 839 may contact a corresponding region (e.g., the connection pad) on the first substrate 810. Then, the projection of the energy beam 159 may be stopped, and the heat may be dissipated by suitable means (e.g., by a fan or other active heat dissipation method; or, passive heat dissipation method by standing for a certain period of time) to allow the electronic component 831 to be bonded to the first substrate 810.

In an embodiment, the energy beam 159 may reduce force between the second substrate 820 and the corresponding electronic component 831. For example, if there is an appropriate temporary adhesive layer between the second substrate 820 and the electronic component 830 disposed thereon, light or heat energy from the energy beam 159 may be used to reduce the bonding force between the second substrate 820 and the corresponding electronic component 831.

In an embodiment, the energy beam generator 150 may include a laser generating mechanism. In an embodiment, the energy beam 159 may include a laser beam. In an embodiment, the configuration position of the energy beam generator 150 may be adjusted according to design requirements.

It should be noted that in the embodiments shown in FIG. 1C to FIG. 1F, the two substrates in the non-parallel configuration are first enabled to contact to each other to form the corresponding contact region, then the two substrates are enabled to be completely in contact, and then the electronic component 830 to be bonded on the second substrate 820 is bonded to the bonded surface 811 of the first substrate 810. In an embodiment not shown, the two substrates in a non-parallel configuration may be first enabled to contact to each other to form the corresponding contact region, then the electronic component 831 to be bonded on the second substrate 820 is bonded onto the bonded surface 811 of the first substrate 810, and then the two substrates are enabled to be completely in contact.

In an embodiment, the electronic components 832 and 833 may be bonded and fixed on the first substrate 810 in the same or similar manner as described above.

Referring to FIG. 1F to FIG. 1G, for example, the suction force of the suction nozzles 131 and 132 may be adjusted or stopped by the driving mechanism 140; and/or, the height of the suction nozzles 131 and 132 may be adjusted so that the first substrate 810 and the second substrate 820 are far away from each other. Moreover, in the process of distancing the first substrate 810 and the second substrate 820 from each other, the corresponding electronic component 830 may be separated from the second substrate 820 because the corresponding electronic component 830 has been bonded on the first substrate 810.

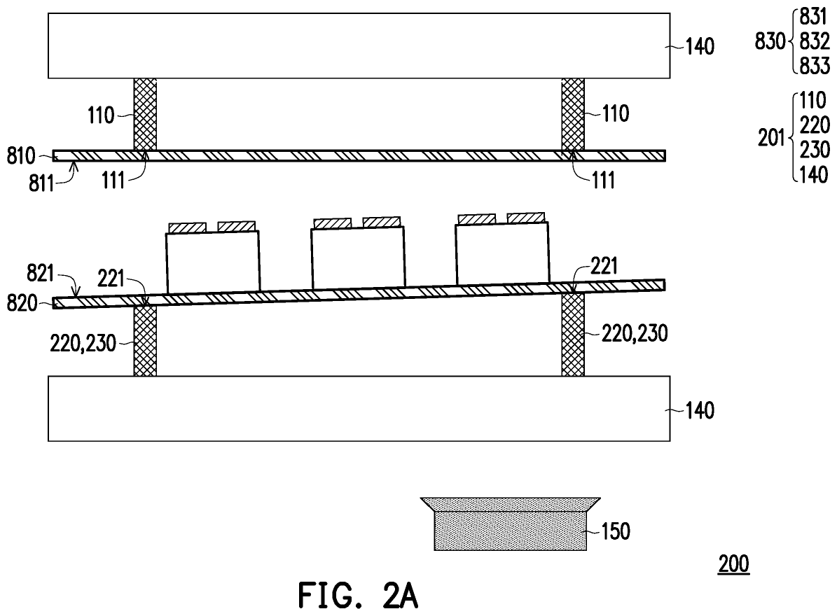

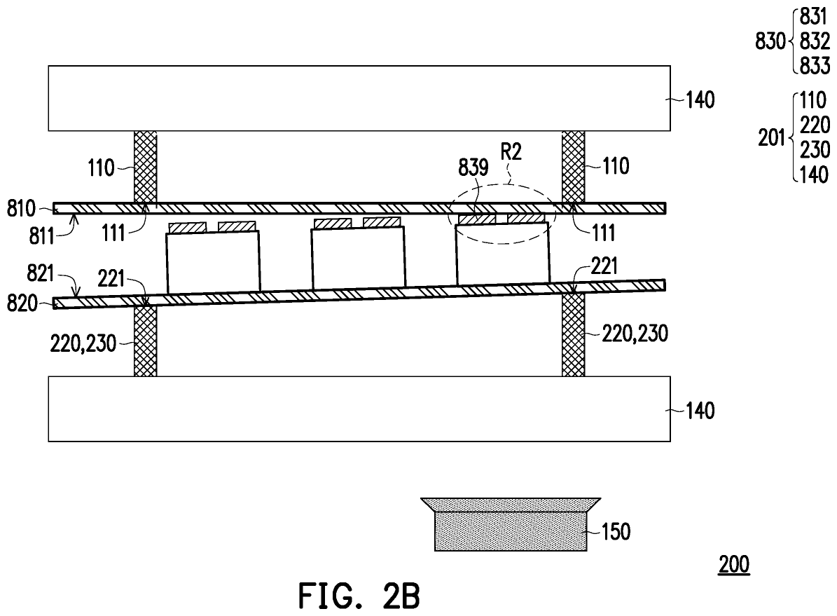

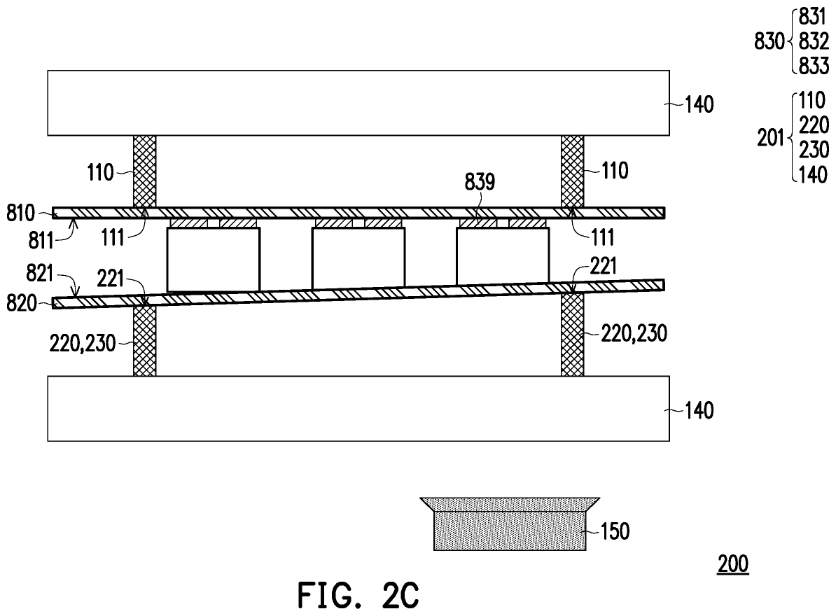

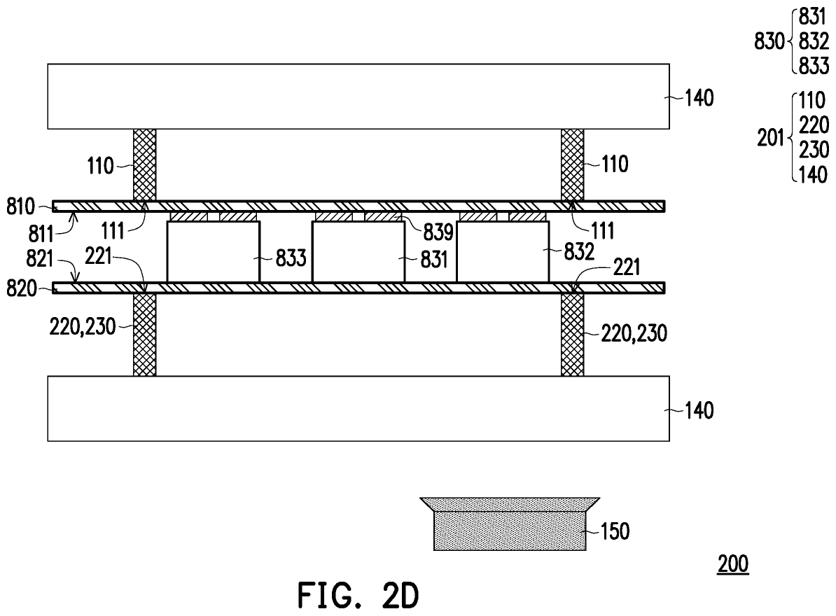

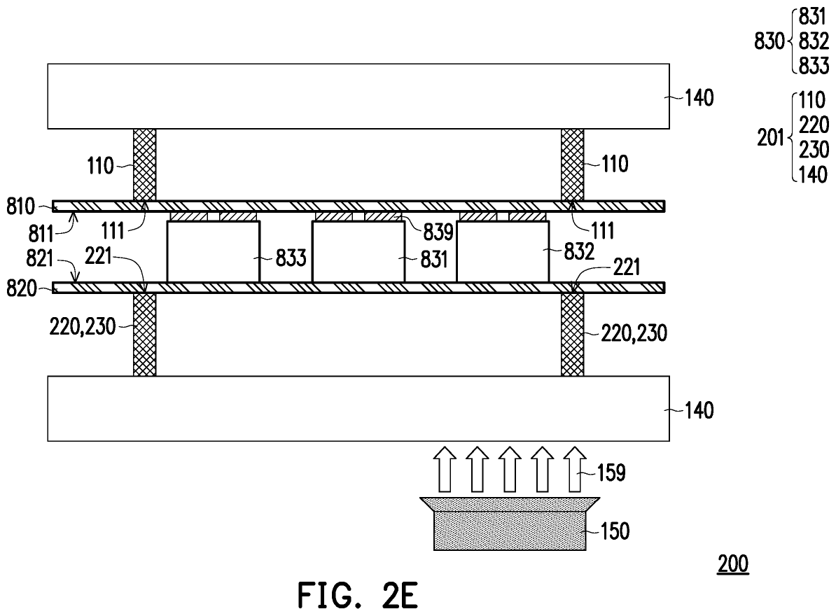

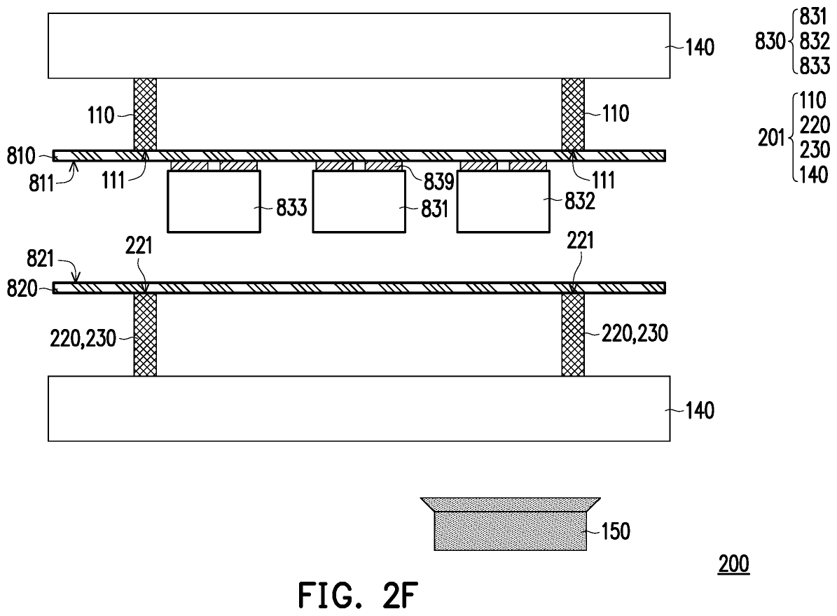

FIG. 2A to FIG. 2F are schematic partial side views of a method for bonding an electronic component according to another embodiment of the disclosure, including a corresponding equipment for attaching substrates and/or an apparatus for bonding an electronic component.

Referring to FIG. 2A or other similar diagrams, an apparatus for bonding an electronic component (may be referred to as: an apparatus) 200 may include an equipment for attaching substrates (may be referred to as: an apparatus) 201 and an energy beam generator 150, and may be adapted to enable an electronic component 830 to be transferred from a second substrate 820 to a first substrate 810 (details will be described later). The equipment for attaching substrates 201 may include a first carrier 110, a second carrier 220, a driving mechanism 140, and a substrate adjustment mechanism 230.

The second carrier 220 may have a second carrying surface 221, so that the second carrier 220 may be adapted to carry the second substrate 820.

In an embodiment, the second carrier 220 and the substrate adjustment mechanism 230 may be the same component. For example, at least two parts of the second carrying surface 221 may be located at different levels. In this way, after the second substrate 820 is placed on the second carrying surface 221 of the second carrier 220, the surface 821 of the second substrate 820 may present a non-horizontal (e.g., tilted) inclined surface, so that the first substrate 810 carried on the first carrying surface 111 of the first carrier 110 and the second substrate 820 carried on the second carrying surface 221 of the second carrier 220 are in a non-parallel configuration.

In an embodiment, the second carrier 220 and the substrate adjustment mechanism 230 may be integrated components. For example, the substrate adjustment mechanism 230 may include a screw or other component adapted to adjust height, and at least two parts of the second carrying surface 221 may be located at different heights through appropriate adjustment.

In an embodiment, the substrate adjustment mechanism 230 may be adjusted by an appropriate movable module (e.g., a vertical moving module).

The driving mechanism 140 may be adapted to directly or indirectly actuate at least one of the first carrier 110 and the second carrier 220, so that the first carrier 110 or the second carrier 220 may be moved and/or rotated in a corresponding direction according to design requirements.

In an embodiment, a method for transferring the electronic component 830 from the second substrate 820 to the first substrate 810 by the apparatus for bonding an electronic component (may be referred to as: the apparatus) 200 may be as follows.

Referring to FIG. 2A, the first substrate 810 is placed on the first carrying surface 111 of the first carrier 110; and/or, the second substrate 820 is placed on the second carrying surface 221 of the second carrier 220. Then, the bonded surface 811 of the first substrate 810 faces the surface 821 of the second substrate 820 having the electronic component 830 to be bonded.

Referring to FIG. 2A to FIG. 2B, for example, the first substrate 810 and the second substrate 820 in the non-parallel configuration may be enabled to approach each other by the driving mechanism 140 and to contact each other to form a contact region R2.

In an embodiment, the contact region R2 is basically located in a peripheral area of the first substrate 810 and the second substrate 820. In an embodiment, compared with other electronic components (e.g., the electronic components 831 and 833 different from the electronic component 832), the electronic component 832 placed at a corresponding height may contact a corresponding position of the first substrate 810 earlier. For example, the conductive connector 839 on the electronic component 832 may contact a corresponding connection pad on the bonded surface 811 of the first substrate 810.

Referring to FIG. 2B to FIG. 2C, in an embodiment, for example, the driving mechanism 140 may enable the first substrate 810 and the second substrate 820 in the non-parallel configuration to further approach each other, so that the two substrates (i.e., the first substrate 810 and second substrate 820) gradually contact with other regions from the contact region R2 until the two substrates 810 and 820 are completely in contact.

In an embodiment, the conductive connector 839 on other electronic components (e.g., the electronic components 831 and 833) different from the electronic component 832 may contact the corresponding connection pad on the bonded surface 811 of the first substrate 810.

Referring to FIG. 2C to FIG. 2D, in an embodiment, after the two substrates 810 and 820 are completely in contact, a height of the substrate adjustment mechanism 230 may be adjusted to enable the surface 821 of the second substrate 820 to appear flat. For example, the height of the substrate adjustment mechanism 230 may be positioned on the same horizontal plane, and the surface 821 of the second substrate 820 may appear flat.

Referring to FIG. 2D to FIG. 2E, in an embodiment, for example, the energy beam generating mechanism 150 may generate the energy beam 159. The energy beam 159 is directed towards and applied to the first substrate 810 or the second substrate 820 to bond the electronic component to be bonded (e.g., the electronic component 832) onto the second substrate 820 to the bonded surface 811 of the first substrate 810.

It should be noted that, in the embodiments shown in FIG. 2B to FIG. 2E, the two substrates in a non-parallel configuration are first enabled to contact to each other to form the corresponding contact region, then the two substrates are enabled to be completely in contact, and then the electronic component 830 to be bonded on the second substrate 820 is bonded to the bonded surface 811 of the first substrate 810. In an embodiment not shown, the two substrates in a non-parallel configuration may be first enabled to contact to each other to form the corresponding contact region, then the electronic component 831 to be bonded on the second substrate 820 is bonded onto the bonded surface 811 of the first substrate 810, and then the two substrates are enabled to be completely in contact.

In an embodiment, the electronic components 831 and 833 may be bonded to the first substrate 810 in the same or similar manner as described above.

Referring to FIG. 2E to FIG. 2F, for example, the driving mechanism 140 may be configured to move the first substrate 810 and the second substrate 820 away from each other. Moreover, in the process of distancing the first substrate 810 and the second substrate 820 from each other, the corresponding electronic component 830 may be separated from the second substrate 820 because the corresponding electronic component 830 has been bonded on the first substrate 810.

All of the components or elements in the drawings may be suitably flipped, rotated, arranged, and/or combined to become components presented in another undrawn drawing. For example, in an undrawn drawing or embodiment, the configuration may be a rotation or up and down flip of FIG. 1A to FIG. 1G or FIG. 2A to FIG. 2F.

The methods for transferring or bonding the electronic component 830 according to the above embodiments may be applicable to any suitable manufacturing process for an electronic component. For example, the electronic component 830 may include light-emitting diode (LED), and the bonding method described above may be a part of a manufacturing process for an LED display.

To sum up, the apparatus of the disclosure may be configured to bond the substrates, and the apparatus of the disclosure may be configured to transfer the electronic component in a relatively simple manner. Furthermore, the apparatus and/or method for bonding the electronic component may improve productivity or yield.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. An apparatus for bonding an electronic component, comprising:
a first carrier configured to carry a first substrate and having a first carrying surface;
a second carrier configured to carry a second substrate having the electronic component to be bonded, and having a second carrying surface;
a driving mechanism enabling the first carrier and the second carrier to move close to and far away from each other;
a substrate adjustment mechanism enabling the carried first substrate and the carried second substrate to be in a non-parallel configuration; and
an energy beam generator generating an energy beam towards the first carrier and the second carrier.

2. The apparatus for bonding an electronic component according to claim 1, wherein the substrate adjustment mechanism comprises two suction nozzles disposed opposite to each other and disposed near the second carrier, the two suction nozzles are not located at positions between the first carrying surface and the second carrying surface and suck air in a direction away from the second carrying surface.

3. The apparatus for bonding an electronic component according to claim 1, wherein the substrate adjustment mechanism arranges the first carrier and the second carrier in a way that the first carrying surface and the second carrying surface are in a non-parallel configuration.

4. The apparatus for bonding an electronic component according to claim 1, wherein the energy beam is a laser beam.

5. A method for bonding an electronic component, comprising:
providing a first substrate having a bonded surface;
providing a second substrate having a surface on which the electronic component to be bonded is disposed;
placing the first substrate and the second substrate in a way that the bonded surface of the first substrate faces the surface of the second substrate on which the electronic component to be bonded is disposed;
arranging the first substrate and the second substrate to be in a non-parallel configuration;
moving the first substrate and/or the second substrate to approach each other in the non-parallel configuration till the first substrate contacts the second substrate at a contact region;
continuing to move the first substrate and/or the second substrate to achieve a full contact of the first substrate and the second substrate from the mere contact of the contact region; and
applying an energy beam to bond the electronic component from the second substrate onto the bonded surface of the first substrate.

6. The method for bonding an electronic component according to claim 5, wherein the contact region is located in a central area of the first substrate and the second substrate.

7. The method for bonding an electronic component according to claim 5, wherein the contact region is located in a peripheral area of the first substrate and the second substrate.

8. The method for bonding an electronic component according to claim 5, wherein the energy beam is a laser beam.

9. The method for bonding an electronic component according to claim 5, wherein the electronic component is a light-emitting diode.

10. A method for manufacturing a light-emitting diode display, comprising:
bonding the light-emitting diode using the method for bonding an electronic component according to claim 9.
